(19) United States
(12) Patent Application Publication
(10) Pub. No.: US 2008/0144865 A1
(43) Pub. Date: Jun. 19, 2008

(54) M-BRIDGE CLASS-D AUDIO AMPLIFIER

(76) Inventor: Bin Xu, Cupertino, CA (US)

Correspondence Address: Gibb & Rahman, LLC, 2568-A RIVA ROAD SUITE 304, ANNAPOLIS, MD, 21401, US

(21) Appl. No.: 11/611,413

(22) Filed: Dec. 15, 2006

(51) Int. Cl. H04R 5/00; H04R 5/02; H03F 21/00

(52) U.S. Cl. 381/309; 381/28; 381/120

(57) ABSTRACT

A M-bridge class-D audio amplifier for portable applications and a method of driving a three-wire audio output device comprises a stereo signal source producing a first and second input stereo digital signal; circuitry adapted to receive the first and second input stereo digital signals and produce three stereo signals comprising a first, second, and third digital signal, wherein the three stereo signals generate pulse-width modulation (PWM) waves comprising a first, second, and third digital signal PWM wave; exactly three pairs of MOSFETs driven by the first, second, and third digital signal PWM waves; and a three-wire speaker system comprising a first wire driven by the first digital signal PWM wave; a second wire driven by the second digital signal PWM wave; and a common wire driven by the third digital signal PWM wave.

### BACKGROUND

1. Technical Field

The embodiments herein generally relate to electrical components, and, more particularly, to class-D audio amplifiers.

2. Description of the Related Art

Class-D is a switching-based audio amplifier technology and theoretically it can achieve approximately 100% power efficiency. Traditional Class-AB audio amplifiers have a much lower efficiency. For portable devices such as MP3 players and multi-media cell phones, etc., where the battery power consumption is critical, users are motivated to use more power efficient class-D audio amplifiers to replace the current market-dominant class-AB amplifiers, which only have approximately 20-30% efficiency for portable digital audio applications.

The class-D audio amplifiers used for portable devices, such as MP3 players, have to support commonly-used and popular three-wire stereo earphones or headphones. The three wires are left, right, and common. The voltage difference between the left and common wires drives the left speaker of the headphone, and the voltage difference between the right and common wires drives the right speaker of the headphone.

Currently, class-D amplifiers are generally based on the so-called H-bridge topology. In order to reduce the electromagnetic interference (EMI), the H-bridge adopts double-sided pulse-width modulation (PWM) waves as shown in FIG. 1, and further described in U.S. Pat. Nos. 6,211,728 and 6,614,297, the complete disclosures of which, in their entireties, are herein incorporated by reference. This technology is typically only good for driving a two-wire speaker. For example, for stereo applications in which two speakers are needed, each speaker has to accept/provide two wires. In total, four wires are needed and they are driven by two H-bridge class-D audio amplifiers, as shown in FIG. 2. This H-bridge class-D amplifier generally cannot be used to drive three-wire earphones or headphones used by portable devices. Accordingly, there remains a need for a class-D audio amplifier capable of driving a three-wire speaker, earphone, or headphone with low EMI.

### SUMMARY

In view of the foregoing, an embodiment herein provides a M-bridge class-D audio system for portable applications comprising a stereo signal source producing a V_left stereo signal and a V_right stereo signal; circuitry adapted to receive the V_left stereo signal and a V_right stereo signal and produce three stereo signals comprising a V_delta signal, a NV_delta signal, and a NV_sigma signal, wherein the three stereo signals generate PWM waves comprising a V_delta PWM wave, a NV_delta PWM wave, and a NV_sigma PWM wave; exactly three pairs of metal-oxide-semiconductor field-effect transistors (MOSFETs) driven by the V_delta PWM wave, the NV_delta PWM wave, and the NV_sigma PWM wave respectively; and a three-wire speaker system comprising a left wire driven by the V_delta PWM wave through a first one of the pair of MOSFETs; a right wire driven by the NV_delta PWM wave through a second one of the pair of MOSFETs; and a common wire driven by the NV_sigma PWM wave through a third one of the pair of MOSFETs.

Preferably, the three stereo signals comprise any of digital stereo signals and analog stereo signals. Moreover, the V_left stereo signal and the V_right stereo signal are preferably sigma-delta-ed in any of a digital domain and an analog domain to produce the three stereo signals. Additionally, the V_delta stereo signal, the NV_delta stereo signal, the NV_sigma stereo signal, the V_left stereo signal, and the V_right stereo signal preferably satisfy: V_delta−NV_sigma=V_left, and NV_delta−NV_sigma=V_right in an audio frequency band. Preferably, the V_delta stereo signal equals (the V_left stereo signal minus the V_right stereo signal)/2; the NV_delta stereo signal equals (the V_right stereo signal minus the V_left stereo signal)/2; and the NV_sigma stereo signal equals—(the V_left stereo signal plus the V_right stereo signal)/2.

Furthermore, the left wire may be double-sided modulated by the V_delta stereo signal and the NV_sigma stereo signal thereby producing the V_left stereo signal equaling the V_delta stereo signal minus the NV_sigma stereo signal in an audio frequency band. Also, the right wire may be double-sided modulated by the NV_delta stereo signal and the NV_sigma stereo signal thereby producing the V_right stereo signal equaling the NV_delta stereo signal minus the NV_sigma stereo signal in an audio frequency band.

Moreover, the stereo signal source may comprise two identical input stereo digital signals (V_mono signal), wherein the system may further comprise a dummy input signal (V_dummy signal) with a frequency higher than approximately 20 khz combined with the V_left stereo signal and the V_right stereo signal such that the V_left stereo signal equals the V_mono signal plus the V_dummy signal; and the V_right stereo signal equals the V_mono signal minus the V_dummy signal. Also, the system may further comprise a low-pass filter adapted to filter out any signal having a frequency component higher than approximately 20 khz. Furthermore, each of the left and right wires may be adapted to filter out any signal having a frequency component higher than approximately 20 khz. Additionally, the three-wire speaker system preferably comprises any of three-wire earphones and headphones.

Another embodiment provides a class-D audio amplifier for portable applications comprising a stereo signal source producing a first input stereo digital signal and a second input stereo digital signal; circuitry adapted to receive the first input stereo digital signal and a second input stereo digital signal and produce three stereo signals comprising a first digital signal, a second digital signal, and a third digital signal, wherein the three stereo signals generate PWM waves comprising a first digital signal PWM wave, a second digital signal PWM wave, and a third digital signal PWM wave; exactly three pairs of MOSFETs driven by the first digital signal PWM wave, the second digital signal PWM wave, and the third digital signal PWM wave respectively; and a three-wire speaker system comprising a first wire driven by the first digital signal PWM wave through a first one of the pair of MOSFETs; a second wire driven by the second digital signal PWM wave through a second one of the pair of MOSFETs; and a common wire driven by the third digital signal PWM wave through a third one of the pair of MOSFETs.

Preferably, the three stereo signals comprise any of digital stereo signals and analog stereo signals. Furthermore, the first input stereo digital signal and the second input stereo digital signal may be sigma-delta-ed in any of a digital domain and an analog domain to produce the three stereo signals. Additionally, the first digital signal stereo signal, the second digital signal stereo signal, the third digital signal stereo signal, the first input stereo digital signal, and the second input stereo digital signal preferably satisfy: first digital signal−third digital signal=the first input stereo digital signal, and second digital signal−third digital signal=the second input stereo digital signal in an audio frequency band.

Preferably, the first digital signal stereo signal equals (the first input stereo digital signal minus the second input stereo digital signal)/2; the second digital signal stereo signal equals (the second input stereo digital signal minus the first input stereo digital signal)/2; and the third digital signal stereo signal equals—(the first input stereo digital signal plus the second input stereo digital signal)/2. Additionally, the first wire may be double-sided modulated by the first digital signal stereo signal and the third digital signal stereo signal thereby producing the first input stereo digital signal equaling the first digital signal stereo signal minus the third digital signal stereo signal in an audio frequency band. Moreover, the second wire may be double-sided modulated by the second digital signal stereo signal and the third digital signal stereo signal thereby producing the second input stereo digital signal equaling the second digital signal stereo signal minus the third digital signal stereo signal in an audio frequency band.

Furthermore, the stereo signal source may comprise two identical input stereo digital signals, wherein the system may further comprise a dummy input signal with a frequency higher than approximately 20 khz combined with the first input stereo digital signal and the second input stereo digital signal such that the first input stereo digital signal equals the identical input stereo digital signal plus the dummy input signal; and the second input stereo digital signal equals the identical input stereo digital signal minus the dummy input signal. Additionally, the amplifier may further comprise a low-pass filter adapted to filter out any signal having a frequency component higher than approximately 20 khz. Moreover, each of the first and second wires may be adapted to filter out any signal having a frequency component higher than approximately 20 khz. Furthermore, the three-wire speaker system preferably comprises any of three-wire earphones and headphones.

Another embodiment provides a method of driving a three-wire audio output device, wherein the method comprises producing a first input stereo digital signal and a second input stereo digital signal; producing three stereo signals from the first input stereo digital signal and the second input stereo digital signal, wherein the three stereo signals comprise a first digital signal, a second digital signal, and a third digital signal, wherein the three stereo signals generate PWM waves comprising a first digital signal PWM wave, a second digital signal PWM wave, and a third digital signal PWM wave; sending the first digital signal PWM wave to a first pair of MOSFETs; sending the second digital signal PWM wave to a second pair of MOSFETs; sending the third digital signal PWM wave to a third pair of MOSFETs; sending the first digital signal PWM wave to a first wire through the first pair of MOSFETs; sending the second digital signal PWM wave to a second wire through the second pair of MOSFETs; and sending the third digital signal PWM wave to a common wire through the third pair of MOSFETs.

Preferably, the three stereo signals comprise any of digital stereo signals and analog stereo signals. Furthermore, the first input stereo digital signal and the second input stereo digital signal may be sigma-delta-ed in any of a digital domain and an analog domain to produce the three stereo signals. Preferably, the first digital signal stereo signal, the second digital signal stereo signal, the third digital signal stereo signal, the first input stereo digital signal, and the second input stereo digital signal satisfy: first digital signal−third digital signal=the first input stereo digital signal, and second digital signal−third digital signal=the second input stereo digital signal in an audio frequency band.

Preferably, the first digital signal stereo signal equals (the first input stereo digital signal minus the second input stereo digital signal)/2; the second digital signal stereo signal equals (the second input stereo digital signal minus the first input stereo digital signal)/2; and the third digital signal stereo signal equals—(the first input stereo digital signal plus the second input stereo digital signal)/2. Moreover, the first wire may be double-sided modulated by the first digital signal stereo signal and the third digital signal stereo signal thereby producing the first input stereo digital signal equaling the first digital signal stereo signal minus the third digital signal stereo signal in an audio frequency band.

Also, the second wire may be double-sided modulated by the second digital signal stereo signal and the third digital signal stereo signal thereby producing the second input stereo digital signal equaling the second digital signal stereo signal minus the third digital signal stereo signal in an audio frequency band. Moreover, the stereo signal source may comprise two identical input stereo digital signals, wherein the method may further comprise combining a dummy input signal with a frequency higher than approximately 20 khz with the first input stereo digital signal and the second input stereo digital signal such that the first input stereo digital signal equals the identical input stereo digital signal plus the dummy input signal; and the second input stereo digital signal equals the identical input stereo digital signal minus the dummy input signal. Additionally, the method may further comprise filtering out any signal having a frequency component higher than approximately 20 khz.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 is a graphical representation illustrating a double-sided pulse-width modulation wave;

FIG. 2 illustrates a schematic diagram of a conventional H-bridge for driving stereo speakers;

FIG. 3 illustrates a schematic block diagram of an all-digital class-D audio amplifier providing signal conditioning according to an embodiment herein;

FIG. 4 illustrates a schematic diagram of a M-bridge for driving three-wire stereo speakers according to an embodiment herein; and

FIG. 5 is a flow diagram illustrating a preferred method according to an embodiment herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

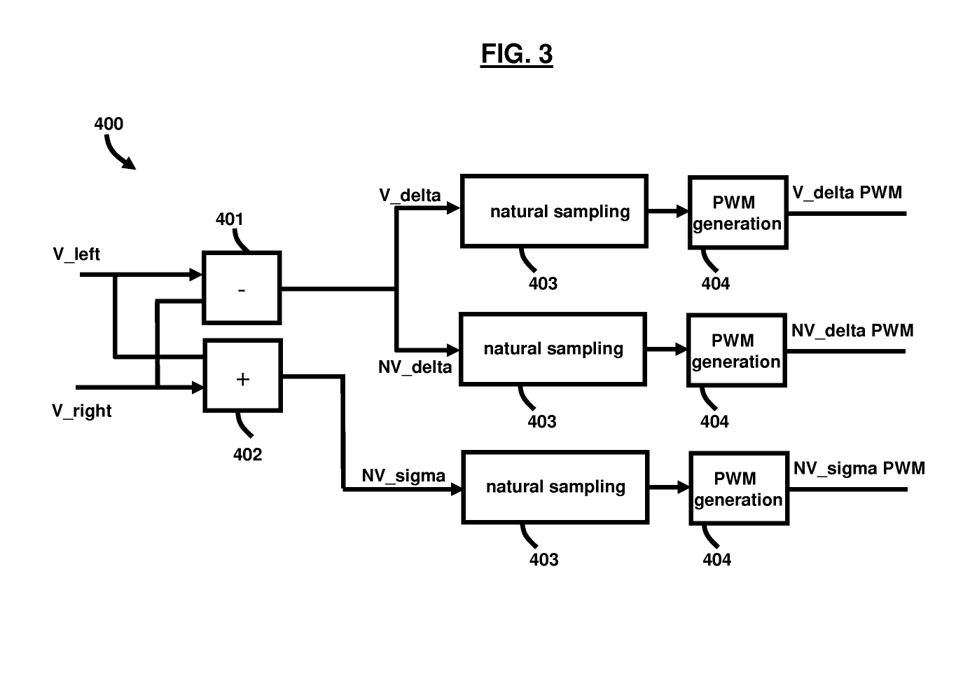

As mentioned, there remains a need for a class-D audio amplifier capable of driving a three-wire stereo speakers, earphones, or headphones. The embodiments herein achieve this by providing a class-D audio amplifier based on an M-bridge topology for use with three-wire stereo speakers, earphones, and/or headphones. Referring now to the drawings, and more particularly to FIGS. 3 through 5, where similar reference characters denote corresponding features consistently throughout the figures, there are shown preferred embodiments.

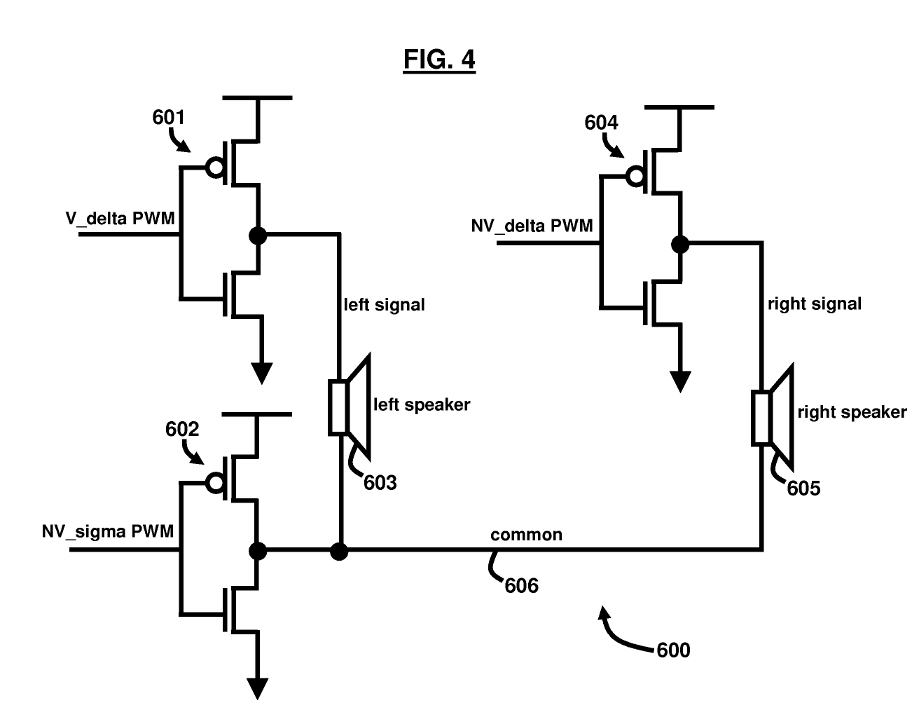

As illustrated in FIGS. 3 and 4, the embodiments herein provide a novel M-bridge topology 600 to make class-D amplifier work for three-wire stereo earphones and headphones for portable devices. The input stereo signals V_left and V_right are sigma-delta-ed to produce three signals, V_delta, NV_delta, and NV_sigma by satisfying the following relationship in the audio frequency band (approximately 0-20 khz):

V_delta−NV_sigma=V_left

NV_delta−NV_sigma=V_right

There are infinite choices of V_delta, NV_delta, and NV_sigma satisfying the above equations. A practical choice can be made according to the following formulas:

V_delta=(V_left−V_right)/2;

NV_delta=−(V_left−V_right)/2;

NV_sigma=−(V_left+V_right)/2.

The input stereo signals V_left and V_right can either be digital in a pulse code modulation (PCM) format, or they can be analog signals by using an audio digital-to-analog converter (DAC) to convert the incoming digital signals into analog signals. Shown in FIG. 3, if the input signals are digital, then the add/subtract operations in the above formulas are performed by digital add 401 and subtract 402 circuits, respectively. If the input signals are analog, the add and subtract operations in the above formulas are performed by analog add 401 and subtract 402 circuits, respectively.

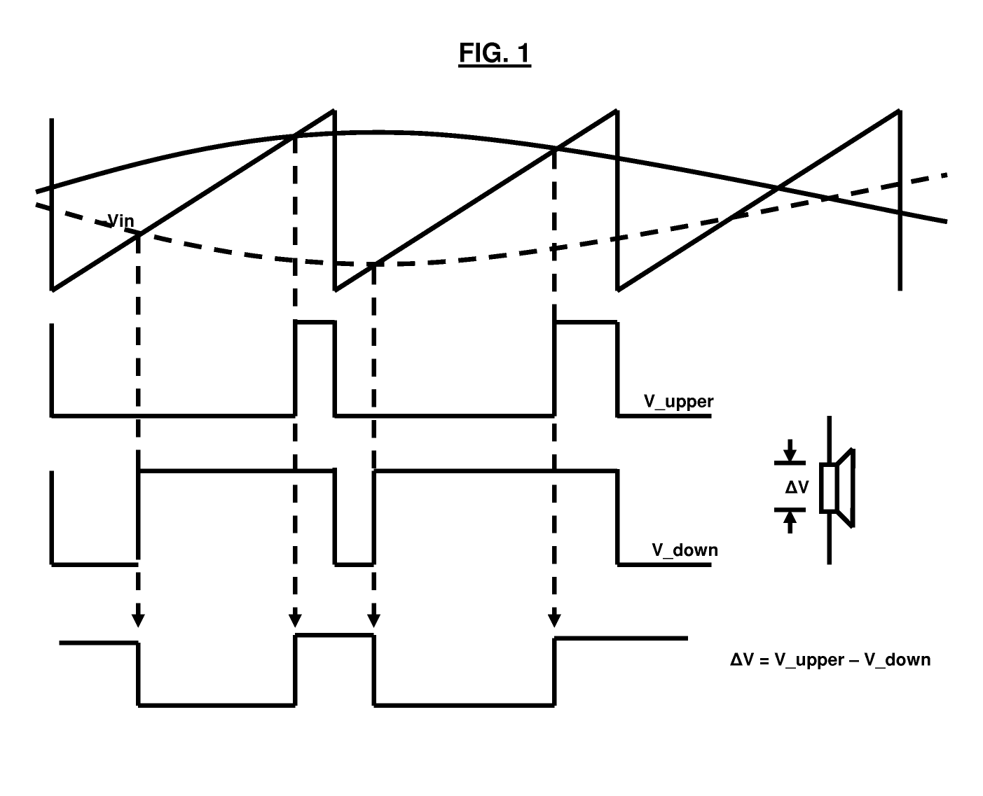

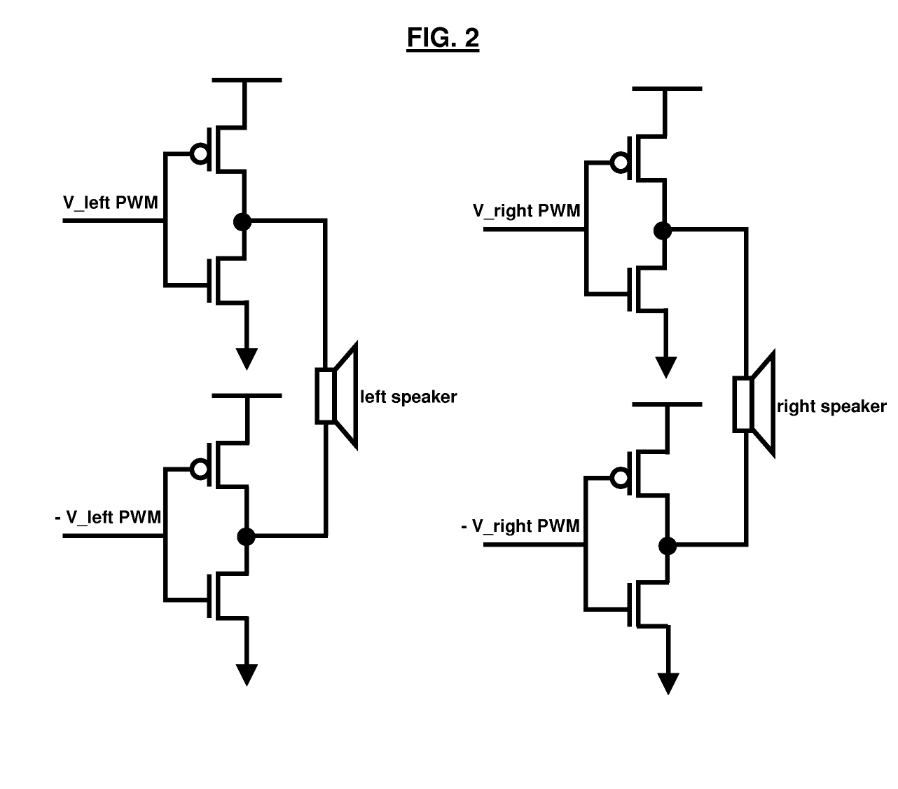

In total, three MOSFET power stages 601, 602, and 604 are electrically connected in parallel and are used in order to drive a three-wire stereo earphone/headphone. The PWM generated by V_delta drives the left wire and the PWM generated by NV_delta drives the right wire. V_delta and NV_delta each go through the naturally sampling 403 and PWM generation 404 steps to generate a V_delta PWM signal and NV_delta PWM signal, respectively. Moreover, the common wire 606 is connected to NV_sigma. NV_sigma goes through the naturally sampling 403 and PWM generation 404 steps to generate a NV_sigma PWM signal. Effectively, the left speaker (wire) 603 is double-sided modulated by V_delta and NV_sigma, producing voltage difference across the left speaker 603 to be V_delta−NV_sigma=V_left signal in audio frequency band, and the right speaker (wire) 605 is double-sided modulated by NV_delta and NV_sigma, producing voltage difference across the right speaker 605 to be NV_delta−NV_sigma=V_right signal in audio frequency band. In other words, both the PWM's rising edge and falling edge are modulated, instead of one edge being fixed and only one edge being modulated which is single-sided PWM. For the PWM wave driving the left speaker 603, its two edges are modulated by V_delta and NV_sigma respectively. For the PWM wave driving the right speaker 605, its two edges are modulated by NV_delta and NV_sigma respectively. Therefore this M-bridge topology 600 makes class-D amplification work with three-wire earphones/headphones meanwhile keeping the EMI as low as in double-sided H-bridge technology (as in FIGS. 1 and 2).

This occurs because now the voltage difference across the left speaker 603 equals to the input V_left signal, and the voltage difference across the right speaker 605 equals to the input V_right signal. In general, the EMI in the M-Bridge topology 600 provided by the embodiments herein is the same level as the double-sided H-bridge topology. Moreover, the M-Bridge 600 keeps the EMI low through double-sided PWM modulation as described above.

In case the input signals are not stereo but is mono (in this case, the stereo left signal and the stereo right signal are the same, equaling to V_mono), in order to guarantee double-sided modulation, a dummy input signal with a frequency higher than the audio band (>20 khz) can be added/subtracted to the input stereo left and right signals to make them behave like stereo input. The pre-processing of the input signals can be done according to the following formulas:

V_left=V_mono+V_dummy

V_right=V_mono−V_dummy

The low-pass filtering property of the audio speaker 603, 605 automatically filters out any frequency component above the audio band (>20 khz). The low-pass filters may be embodied in the audio speakers 603, 605 themselves as the speakers 603, 605 may be configured with a cut-off frequency at the audio band upper limit of 20 khz, or alternatively, low-pass LC filters (not shown) can be added to each side of the respective speaker 603, 605. Accordingly, the dummy signal is automatically removed from the left and right speakers 603, 605, respectively.

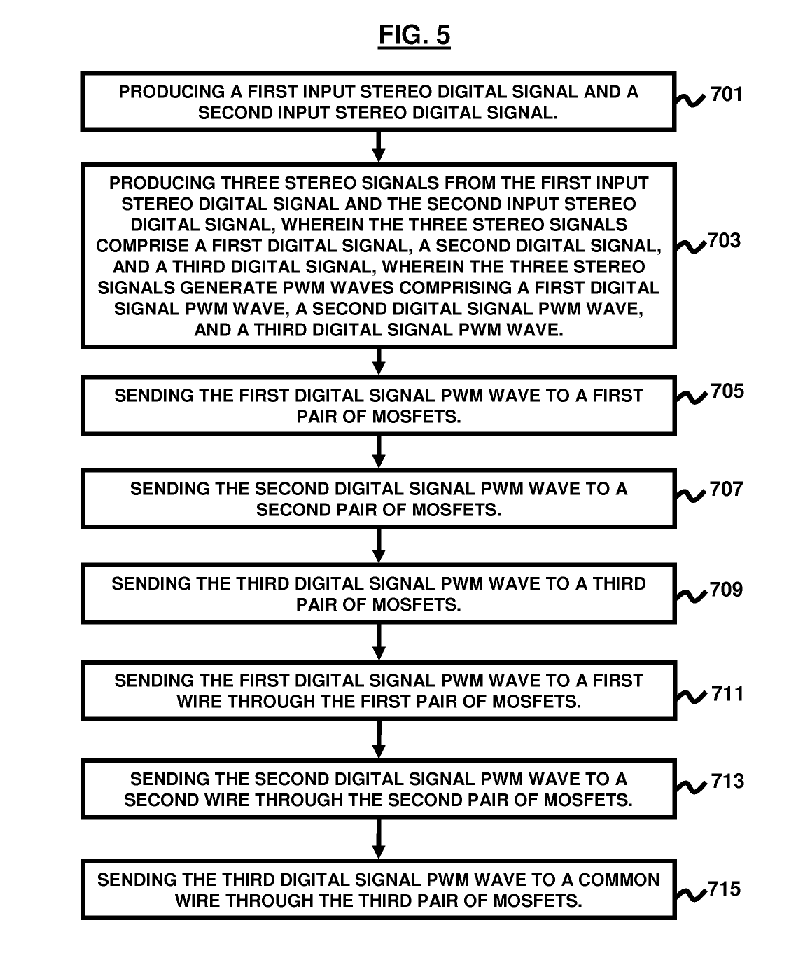

FIG. 5, with reference to FIGS. 3 and 4, is a flow diagram illustrating a method of driving a three-wire audio output device 600 according to an embodiment herein, wherein the method comprises producing (701) a first input stereo digital signal (V_left stereo signal) and a second input stereo digital signal (V_right stereo signal); producing (703) three stereo signals from the first input stereo digital signal (V_left stereo signal) and the second input stereo digital signal (V_right stereo signal), wherein the three stereo signals comprise a first digital signal (V_delta signal), a second digital signal (NV_delta signal), and a third digital signal (NV_sigma signal), wherein the three stereo signals generate PWM waves comprising a first digital signal PWM (V_delta PWM) wave, a second digital signal PWM (NV_delta PWM) wave, and a third digital signal PWM (NV_sigma PWM) wave; sending (705) the first digital signal PWM (V_delta PWM) wave to a first pair of MOSFETs 601; sending (707) the second digital signal PWM (NV_delta PWM) wave to a second pair of MOSFETs 604; sending (709) the third digital signal PWM (NV_sigma PWM) wave to a third pair of MOSFETs 602; sending (711) the first digital signal PWM (V_delta PWM) wave to a first wire (left speaker 603) through the first pair of MOSFETs 601; sending (713) the second digital signal PWM (NV_delta PWM) wave to a second wire (right speaker 605) through the second pair of MOSFETs 604; and sending (715) the third digital signal PWM (NV_sigma PWM) wave to a common wire 606 through the third pair of MOSFETs 602.

Preferably, the three stereo signals comprise any of digital stereo signals and analog stereo signals. Furthermore, the first input stereo digital signal (V_left stereo signal) and the second input stereo digital signal (V_right stereo signal) may be sigma-delta-ed in any of a digital domain and an analog domain to produce the three stereo signals. Preferably, the first digital signal (V_delta signal) stereo signal, the second digital signal (NV_delta signal) stereo signal, the third digital signal (NV_sigma signal) stereo signal, the first input stereo digital signal (V_left stereo signal), and the second input stereo digital signal (V_right stereo signal) satisfy: first digital signal−third digital signal=the first input stereo digital signal, and second digital signal−third digital signal=the second input stereo digital signal in an audio frequency band.

Moreover, the first digital signal (V_delta signal) stereo signal preferably equals (the first input stereo digital signal minus the second input stereo digital signal)/2; the second digital signal stereo signal equals (the second input stereo digital signal minus the first input stereo digital signal)/2; and the third digital signal stereo signal equals—(the first input stereo digital signal plus the second input stereo digital signal)/2. Additionally, the first wire (left speaker 603) may be double-sided modulated by the first digital (V_delta signal) stereo signal and the third digital (NV_sigma signal) stereo signal thereby producing the first input stereo digital signal (V_left stereo signal) equaling the first digital signal stereo signal minus the third digital signal stereo signal in an audio frequency band. Also, the second wire (right speaker 605) may be double-sided modulated by the second digital signal (NV_delta signal) stereo signal and the third digital signal (NV_sigma signal) stereo signal thereby producing the second input stereo digital signal (V_right stereo signal) equaling the second digital signal (NV_delta signal) stereo signal minus the third digital signal (NV_sigma signal) stereo signal in an audio frequency band.

Furthermore, the stereo signal source may comprise two identical input stereo digital signals, wherein the method may further comprise combining a dummy input signal with a frequency higher than approximately 20 khz with the first input stereo digital signal (V_left stereo signal) and the second input stereo digital signal (V_right stereo signal) such that the first input stereo digital signal (V_left stereo signal) equals the identical input stereo digital signal plus the dummy input signal; and the second input stereo digital signal (V_right stereo signal) equals the identical input stereo digital signal minus the dummy input signal. Moreover, the method may further comprise filtering out any signal having a frequency component higher than approximately 20 khz.

The techniques provided by the embodiments herein may be implemented on an integrated circuit (IC) chip or using printable electronic technologies (not shown). The chip or printable electronic circuit design is created in a graphical computer programming language, and stored in a computer storage medium (such as a disk, tape, physical hard drive, or virtual hard drive such as in a storage access network). If the designer does not fabricate chips or printable electronic circuits or the photolithographic masks used to fabricate chips or printable electronic circuits, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII or CIF) for the fabrication of photolithographic masks, which typically include multiple copies of the chip design in question that are to be formed on a wafer or printed on a suitable substrate. The photolithographic masks are utilized to define areas of the wafer or printable electronic circuits (and/or the layers thereon) to be etched or otherwise processed or printed.

The resulting integrated circuit chips or printable electronic circuits can be distributed by the fabricator in raw wafer form (that is, as a single wafer that has multiple unpackaged chips), as a bare die, or in a packaged form or as individual printed circuits or in a sheet or roll of printed circuits. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip might then be integrated with other chips, discrete circuit elements, and/or other signal processing devices as part of either (a) an intermediate product, such as a mother or daughter-board, or (b) an end product. The end product can be any product that includes integrated circuit chip or chips and/or printed circuits, ranging from toys and other low-end applications to advanced computer products having a display, a keyboard or other input device, and a central processor.

The techniques provided by the embodiments herein may also be implemented on printed circuit board (PCB) using discrete components. In this case, the electronic circuit components described herein, such as add/subtract circuits, natural-sampling, noise shaping, and a MOSFET pair, can use discrete components and these discrete components are electronically connected on the printed circuit board to perform the functions of the all-digital class-D audio amplifier 400 described herein.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A M-bridge class-D audio system for portable applications comprising:
a stereo signal source producing a V_left stereo signal and a V_right stereo signal;
circuitry adapted to receive said V_left stereo signal and a V_right stereo signal and produce three stereo signals comprising a V_delta signal, a NV_delta signal, and a NV_sigma signal, wherein said three stereo signals generate pulse-width modulation (PWM) waves comprising a V_delta PWM wave, a NV_delta PWM wave, and a NV_sigma PWM wave;
exactly three pairs of metal-oxide-semiconductor field-effect transistors (MOSFETs) driven by said V_delta PWM wave, said NV_delta PWM wave, and said NV_sigma PWM wave respectively; and
a three-wire speaker system comprising:
a left wire driven by said V_delta PWM wave through a first one of said pair of MOSFETs;
a right wire driven by said NV_delta PWM wave through a second one of said pair of MOSFETs; and
a common wire driven by said NV_sigma PWM wave through a third one of said pair of MOSFETs.

2. The system of claim 1, wherein said three stereo signals comprise any of digital stereo signals and analog stereo signals.

3. The system of claim 1, wherein said V_left stereo signal and said V_right stereo signal are sigma-delta-ed in any of a digital domain and an analog domain to produce said three stereo signals.

4. The system of claim 3, wherein said V_delta stereo signal, said NV_delta stereo signal, said NV_sigma stereo signal, said V_left stereo signal, and said V_right stereo signal satisfy: V_delta−NV_sigma=V_left, and NV_delta−NV_sigma=V_right in an audio frequency band.

5. The system of claim 3, wherein said V_delta stereo signal equals (said V_left stereo signal minus said V_right stereo signal)/2; said NV_delta stereo signal equals (said V_right stereo signal minus said V_left stereo signal)/2; and said NV_sigma stereo signal equals —(said V_left stereo signal plus said V_right stereo signal)/2.

6. The system of claim 3, wherein said left wire is double-sided modulated by said V_delta stereo signal and said NV_sigma stereo signal thereby producing said V_left stereo signal equaling said V_delta stereo signal minus said NV_sigma stereo signal in an audio frequency band.

7. The system of claim 3, wherein said right wire is double-sided modulated by said NV_delta stereo signal and said NV_sigma stereo signal thereby producing said V_right stereo signal equaling said NV_delta stereo signal minus said NV_sigma stereo signal in an audio frequency band.

8. The system of claim 3, wherein said stereo signal source comprises two identical input stereo digital signals (V_mono signal), wherein said system further comprises a dummy input signal (V_dummy signal) with a frequency higher than approximately 20 khz combined with said V_left stereo signal and said V_right stereo signal such that said V_left stereo signal equals said V_mono signal plus said V_dummy signal; and said V_right stereo signal equals said V_mono signal minus said V_dummy signal.

9. The system of claim 8, further comprising a low-pass filter adapted to filter out any signal having a frequency component higher than approximately 20 khz.

10. The system of claim 8, wherein each of the left and right wires are adapted to filter out any signal having a frequency component higher than approximately 20 khz.

11. The system of claim 1, wherein said three-wire speaker system comprises any of three-wire earphones and headphones.

12. A class-D audio amplifier for portable applications comprising:
a stereo signal source producing a first input stereo digital signal and a second input stereo digital signal;
circuitry adapted to receive said first input stereo digital signal and a second input stereo digital signal and produce three stereo signals comprising a first digital signal, a second digital signal, and a third digital signal, wherein said three stereo signals generate pulse-width modulation (PWM) waves comprising a first digital signal PWM wave, a second digital signal PWM wave, and a third digital signal PWM wave;
exactly three pairs of metal-oxide-semiconductor field-effect transistors (MOSFETs) driven by said first digital signal PWM wave, said second digital signal PWM wave, and said third digital signal PWM wave respectively; and
a three-wire speaker system comprising:
a first wire driven by said first digital signal PWM wave through a first one of said pair of MOSFETs;
a second wire driven by said second digital signal PWM wave through a second one of said pair of MOSFETs; and
a common wire driven by said third digital signal PWM wave through a third one of said pair of MOSFETs.

13. The amplifier of claim 12, wherein said three stereo signals comprise any of digital stereo signals and analog stereo signals.

14. The amplifier of claim 12, wherein said first input stereo digital signal and said second input stereo digital signal are sigma-delta-ed in any of a digital domain and an analog domain to produce said three stereo signals.

15. The amplifier of claim 14, wherein said first digital signal stereo signal, said second digital signal stereo signal, said third digital signal stereo signal, said first input stereo digital signal, and said second input stereo digital signal satisfy: first digital signal−third digital signal=said first input stereo digital signal, and second digital signal−third digital signal said second input stereo digital signal in an audio frequency band.

16. The amplifier of claim 14, wherein said first digital signal stereo signal equals (said first input stereo digital signal minus said second input stereo digital signal)/2; said second digital signal stereo signal equals (said second input stereo digital signal minus said first input stereo digital signal)/2; and said third digital signal stereo signal equals—(said first input stereo digital signal plus said second input stereo digital signal)/2.

17. The amplifier of claim 14, wherein said first wire is double-sided modulated by said first digital signal stereo signal and said third digital signal stereo signal thereby producing said first input stereo digital signal equaling said first digital signal stereo signal minus said third digital signal stereo signal in an audio frequency band.

18. The amplifier of claim 14, wherein said second wire is double-sided modulated by said second digital signal stereo signal and said third digital signal stereo signal thereby producing said second input stereo digital signal equaling said second digital signal stereo signal minus said third digital signal stereo signal in an audio frequency band.

19. The amplifier of claim 14, wherein said stereo signal source comprises two identical input stereo digital signals, wherein said system further comprises a dummy input signal with a frequency higher than approximately 20 khz combined with said first input stereo digital signal and said second input stereo digital signal such that said first input stereo digital signal equals the identical input stereo digital signal plus said dummy input signal; and said second input stereo digital signal equals said identical input stereo digital signal minus said dummy input signal.

20. The amplifier of claim 19, further comprising a low-pass filter adapted to filter out any signal having a frequency component higher than approximately 20 khz.

21. The amplifier of claim 19, wherein each of the first and second wires are adapted to filter out any signal having a frequency component higher than approximately 20 khz.

22. The amplifier of claim 12, wherein said three-wire speaker system comprises any of three-wire earphones and headphones.

23. A method of driving a three-wire audio output device, said method comprising:
producing a first input stereo digital signal and a second input stereo digital signal;
producing three stereo signals from said first input stereo digital signal and said second input stereo digital signal, wherein said three stereo signals comprise a first digital signal, a second digital signal, and a third digital signal, wherein said three stereo signals generate pulse-width modulation (PWM) waves comprising a first digital signal PWM wave, a second digital signal PWM wave, and a third digital signal PWM wave;
sending said first digital signal PWM wave to a first pair of metal-oxide-semiconductor field-effect transistors (MOSFETs);
sending said second digital signal PWM wave to a second pair of MOSFETs;
sending said third digital signal PWM wave to a third pair of MOSFETs;
sending said first digital signal PWM wave to a first wire through said first pair of MOSFETs;
sending said second digital signal PWM wave to a second wire through said second pair of MOSFETs; and
sending said third digital signal PWM wave to a common wire through said third pair of MOSFETs.

24. The method of claim 23, wherein said three stereo signals comprise any of digital stereo signals and analog stereo signals.

25. The method of claim 23, wherein said first input stereo digital signal and said second input stereo digital signal are sigma-delta-ed in any of a digital domain and an analog domain to produce said three stereo signals.

26. The method of claim 25, wherein said first digital signal stereo signal, said second digital signal stereo signal, said third digital signal stereo signal, said first input stereo digital signal, and said second input stereo digital signal satisfy: first digital signal−third digital signal=said first input stereo digital signal, and second digital signal−third digital signal said second input stereo digital signal in an audio frequency band.

27. The method of claim 25, wherein said first digital signal stereo signal equals (said first input stereo digital signal minus said second input stereo digital signal)/2; said second digital signal stereo signal equals (said second input stereo digital signal minus said first input stereo digital signal)/2; and said third digital signal stereo signal equals—(said first input stereo digital signal plus said second input stereo digital signal)/2.

28. The method of claim 25, wherein said first wire is double-sided modulated by said first digital signal stereo signal and said third digital signal stereo signal thereby producing said first input stereo digital signal equaling said first digital signal stereo signal minus said third digital signal stereo signal in an audio frequency band.

29. The method of claim 25, wherein said second wire is double-sided modulated by said second digital signal stereo signal and said third digital signal stereo signal thereby producing said second input stereo digital signal equaling said second digital signal stereo signal minus said third digital signal stereo signal in an audio frequency band.

30. The method of claim 25, wherein said stereo signal source comprises two identical input stereo digital signals, wherein said method further comprises combining a dummy input signal with a frequency higher than approximately 20 khz with said first input stereo digital signal and said second input stereo digital signal such that said first input stereo digital signal equals the identical input stereo digital signal plus said dummy input signal; and said second input stereo digital signal equals said identical input stereo digital signal minus said dummy input signal.

31. The method of claim 30, further comprising filtering out any signal having a frequency component higher than approximately 20 khz.
